(19) United States
(12) Patent Application Publication
(10) Pub. No.: US 2018/0337069 A1
(43) Pub. Date: Nov. 22, 2018

(54) SYSTEMS AND METHODS FOR DETECTING UNDESIRABLE DYNAMIC BEHAVIOR OF LIQUID DISPENSED ONTO A ROTATING SUBSTRATE

(71) Applicant: Lam Research AG, Villach (AT)

(72) Inventors: Dipl. -Ing. Dr.techn. Felix Staudegger, St. Kanzian (AT); Ante Plazonic, Feistritz/Drau (AT)

(21) Appl. No.: 15/598,275

(22) Filed: May 17, 2017

(51) Int. Cl. H01L 21/67; H01L 21/687

(52) U.S. Cl. CPC H01L 21/67023; H01L 21/67115; H01L 21/68714; H01L 21/67253; H01L 21/67248

(57) ABSTRACT

A spin chuck for processing a substrate includes a chuck configured to engage and rotate a substrate. A heating assembly is configured to heat at least one surface of the substrate. A liquid dispensing arm is moveable relative to the substrate and includes a liquid dispensing nozzle attached to the liquid dispensing arm to dispense liquid onto the substrate as the substrate is rotated. A first pyrometer is attached to the liquid dispensing arm and is directed at the liquid dispensed by the liquid dispensing nozzle onto the substrate.

### FIELD

The present disclosure relates to spin chucks, and more particularly to systems and methods for detecting undesirable dynamic behavior of liquid dispensed onto a rotating substrate.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrates such as semiconductor wafers are subjected to various surface treatment processes such as etching, cleaning, polishing and material deposition. To accommodate such processes, a spin chuck may be used to engage and rotate a substrate while a liquid dispensing arm delivers liquid onto the substrate as the substrate is rotated. As the liquid is dispensed onto the substrate, undesirable dynamic behavior such as splashing and spiraling of the liquid may occur.

### SUMMARY

A spin chuck for processing a substrate includes a chuck configured to engage and rotate a substrate. A heating assembly is configured to heat at least one surface of the substrate. A liquid dispensing arm is moveable relative to the substrate and includes a liquid dispensing nozzle attached to the liquid dispensing arm to dispense liquid onto the substrate as the substrate is rotated. A first pyrometer is attached to the liquid dispensing arm and is directed at the liquid dispensed by the liquid dispensing nozzle onto the substrate.

In other features, the liquid dispensed by the liquid dispensing nozzle impacts the substrate at a liquid impact location and forms a tail adjacent to and downstream from the liquid impact location. A sensing location of the first pyrometer is directed at the tail of the liquid dispensed onto the substrate and is spaced from the liquid impact location.

In other features, a distance from a center of the liquid impact location to a center of the sensing location is in a range from 5 to 100 mm. A distance from a center of the liquid impact location to a center of the sensing location is in a range from 10 to 50 mm. A center of the sensing location is spaced from a rotational center of the substrate by a first distance that is in a range from 1 to 20 mm more than a second distance from a center of the liquid impact location to the rotational center of the substrate.

In other features, a transmissivity spectrum of the liquid has a local minimum at an infrared wavelength and a measurement wavelength of the first pyrometer corresponds to the infrared wavelength of the local minimum. The infrared wavelength is between at least one of 3.3 and 3.5 micrometers and 8.6 and 9.1 micrometers, for measuring at a transmissivity minimum of the liquid when the liquid includes a secondary alcohol.

In other features, the infrared wavelength is between at least one of 3.3 and 3.5 micrometers and 9.1 and 9.6 micrometers, for measuring at a transmissivity minimum of the liquid when the liquid includes a primary alcohol.

In other features, the infrared wavelength is between 8.6 and 9.6 micrometers.

In other features, a controller, in communication with the first pyrometer, is configured to detect undesirable liquid flow behavior based on an output of the first pyrometer. The controller detects the undesirable liquid flow behavior by comparing an output of the first pyrometer to a predetermined pyrometer output.

In other features, a controller, in communication with the first pyrometer, is configured to control the heating assembly to adjust a temperature of the substrate in a closed loop manner based on an output of the first pyrometer. A second pyrometer is connected to the liquid dispensing arm and is directed at the liquid dispensed onto the substrate. A controller, in communication with the first pyrometer, is configured to at least one of adjust a temperature of the heating assembly based on an output of the first pyrometer and detect undesirable liquid flow behavior based on an output of the second pyrometer.

In other features, an infrared wavelength detected by the first pyrometer is greater than 6.5 micrometers and an infrared wavelength detected by the second pyrometer is between 3 and 4 micrometers.

In other features, the heating assembly includes an array of light emitting diodes (LEDs). The liquid dispensing arm moves the liquid dispensing nozzle and the first pyrometer from a center to an edge of the substrate. The liquid dispensing arm maintains a predetermined distance between the first pyrometer and the substrate as the liquid dispensing arm moves the liquid dispensing nozzle and the first pyrometer.

In other features, an infrared wavelength of the pyrometer is between at least one of 2.7 and 3.3 micrometers and 5.9 and 6.3 micrometers, for measuring at a transmissivity minimum of the liquid when the liquid is an aqueous solution.

In other features, a transmissivity spectrum of the liquid is less than 60% at an infrared wavelength and a measurement wavelength of the first pyrometer corresponds to the infrared wavelength.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a cross-sectional view of an example of a spin chuck according to the present disclosure;

FIG. 2 is a perspective view of an example of a liquid dispensing arm including a liquid nozzle, a pyrometer, a substrate and a spin chuck according to the present disclosure;

FIG. 3 is a plan view of the liquid nozzle, the pyrometer, the substrate and the spin chuck according to the present disclosure;

FIG. 4 is a functional block diagram of an example of a control system for the spin chuck according to the present disclosure;

FIG. 5 is a flowchart illustrating an example of a method for controlling a temperature of the substrate using a pyrometer according to the present disclosure;

FIG. 6 is a flowchart illustrating an example of a method for detecting undesirable dynamic behavior of liquid dispensed onto a substrate using a pyrometer according to the present disclosure; and

FIGS. 7-9 are graphs illustrating temperature as a function of time during normal, spiraling and splashing dynamic liquid behavior.

In the drawings, reference numbers may be reused to identify similar and/or identical elements.

### DETAILED DESCRIPTION

Systems and methods according to the present disclosure include a spin chuck with a moveable liquid dispensing arm. The spin chuck engages and rotates the substrate during treatment. The moveable liquid dispensing arm includes a nozzle and one or more pyrometers that travel with the moveable liquid dispensing arm in a radial direction or along an arcuate path relative to the substrate. A heating assembly is used to heat the substrate.

During substrate treatment such as rinsing, etching and drying, the pyrometer may be used to measure a temperature of the liquid and to detect undesirable dynamic behavior of the dispensed liquid such as splashing and spiraling. A transmissivity spectrum of the dispensed liquid typically has a local minimum at one or more infrared wavelengths. A measurement wavelength of the pyrometer is selected to correspond to one of the infrared wavelengths of the local minimum(s). As a result, the temperature measured by the pyrometer corresponds to the temperature of the liquid and not the temperature of the substrate. However, if liquid is absent (due to splashing or spiraling) the pyrometer detects the temperature of the substrate and a surface underneath. If the substrate is silicon and the detection wavelength is selected where silicon is transparent the temperature of silicon is not detected but rather only the temperature of a surface underneath. Such surface might be cooler or hotter, which is why the detected temperature once the liquid film is opened can be used as an indication for splashing or spiraling.

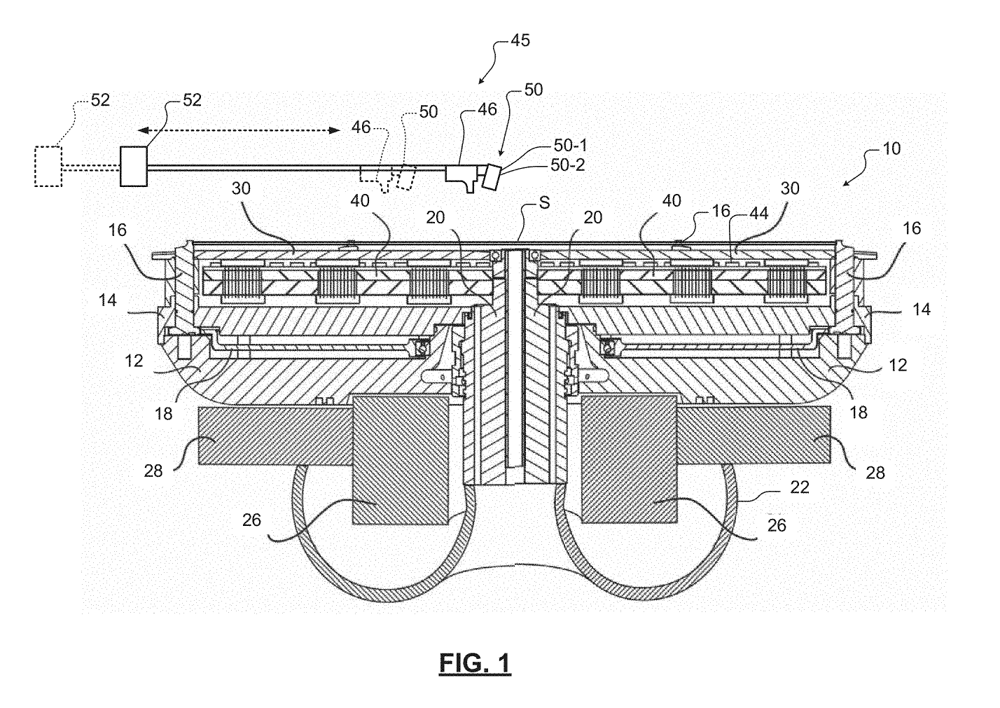

Referring now to FIG. 1, an example of a spin chuck 10 is shown. While a specific type of spin chuck is shown and described herein for purposes of illustration, other types of spin chucks can be used. The spin chuck 10 engages and rotates a substrate S of a predetermined diameter, for example 300 mm or 450 mm. The spin chuck 10 includes a lower chuck body 12 and an upper chuck body 14. Radially outer edges of the substrate S are held by a plurality of pins 16. A ring gear 18 engages ends of the pins 16 via gear teeth. The ring gear 18 rotates relative to the spin chuck 10 to rotate the pins 16 between an open position and a closed position (for engaging a radially outer edge of the substrate S). The lower chuck body 12 and the upper chuck body 14 are secured to one another and are journaled for rotation about a stationary post 20.

The pins 16 pass through openings in a transparent plate 30. In some examples, the transparent plate 30 is made of quartz or sapphire, although other materials can be used. The transparent plate 30 rotates with the spin chuck 10. When the substrate S is positioned on the spin chuck 10, the substrate S is held above the transparent plate 30 so that a lower surface of the substrate S is parallel to the transparent plate 30 and spaced therefrom by a gap.

A heating assembly 40 is shown mounted beneath the transparent plate 30. As can be appreciated, the heating assembly 40 can be mounted above the substrate S. A liquid dispensing arm 45 including a liquid nozzle 46 and a pyrometer 50-1 is arranged above the substrate S. An arm actuator 52 may be used to move the liquid dispensing arm 45 in a radial direction as shown or to rotate a radially outer end of the liquid dispensing arm 45 in an arcuate path across the substrate S.

In some examples, the heating assembly 40 heats the substrate to a predetermined temperature that is close to a boiling temperature of the liquid that is used. In some examples, the predetermined temperature is set within a range of the boiling temperature of the liquid minus 20 Kelvin (K) to plus 5 degrees K. In other examples, the predetermined temperature is set within a range of the boiling temperature of the liquid minus 10 Kelvin (K) to plus 3 degrees K. In some examples, the heating assembly 40 includes multiple zones that can be independently controlled and performs rapid localized heating of the substrate along a moving front to evaporate the liquid sufficiently quickly that a meniscus is not formed and pattern collapse is avoided. Additional details relating to the heating assembly 40 and rapid localized heating along the moving front can be found in “Method And Apparatus for Processing Wafer-Shaped Articles”, U.S. patent application Ser. No. 15/169,330, which was filed on May 31, 2016 and which is hereby incorporated by reference in its entirety.

The stationary post 20 and a stator 28 are mounted on a frame 22. A rotor 26 is secured to the lower chuck body 12. The rotor 26 and the stator 28 may form a magnetic motor that rotates the spin chuck 10, although other types of motors can be used. In some examples, the heating assembly 40 includes a plurality of light emitting diodes (LEDs) 44 mounted in a direction facing the transparent plate 30, although other radiant heat sources can be used.

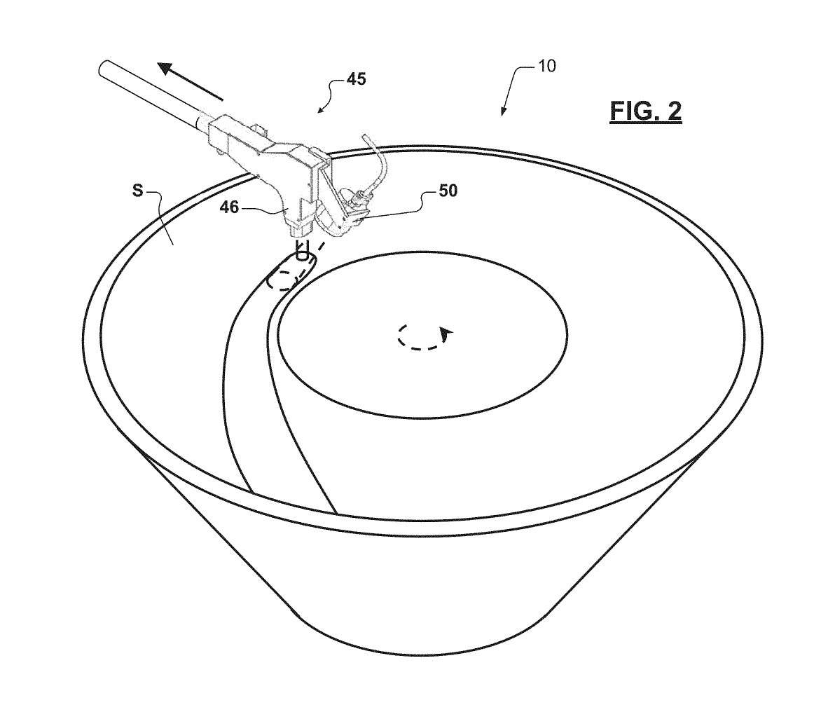

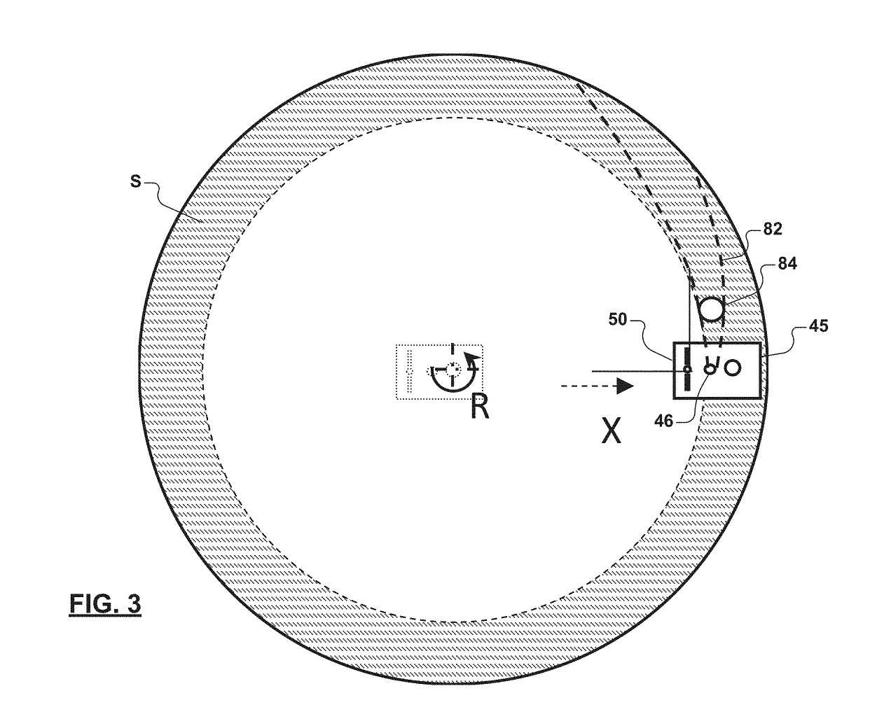

Referring now to FIGS. 2 and 3, liquid is dispensed downwardly onto the substrate S by the liquid nozzle 46 associated with the liquid dispensing arm 45. The liquid that is dispensed by the liquid nozzle 46 impacts the substrate at a liquid impact location 80. Since the substrate S is rotating in a direction indicated by arrow R, the liquid creates an arcuate tail pattern 82 adjacent to and downstream from the liquid impact location 80. A sensing location 84 of the pyrometer 50-1 is directed at a predetermined location within the arcuate tail pattern 82 of the liquid dispensed onto the substrate S. In some examples, the distance from a center of the impact location 80 to a center of the sensing location 84 is in a range from 5 mm to 100 mm. In other examples, the distance from the center of impact location 80 to the center of the sensing location 84 is in a range from 10 mm to 50 mm. In some examples, the center of the sensing location 84 is spaced from a rotational center of the substrate S by a first distance that is 1 mm to 20 mm more than a second distance from the center of the impact location to the rotational center of the substrate S.

A transmissivity spectrum of the liquid that is dispensed typically has a local minimum at one or more infrared wavelengths. A measurement wavelength of the pyrometer 50-1 is selected to correspond to one of the infrared wavelengths of the local minimum(s). For example when the liquid comprises a secondary alcohol such as isopropanol, the infrared wavelength is between one of 3.3 and 3.5 micrometers and 8.6 and 9.1 micrometers. In another example when the liquid comprises a primary alcohol such as n-propanol, the infrared wavelength is between one of 3.3 and 3.5 micrometers and 9.1 and 9.6 micrometers.

In some examples, the infrared wavelength is between 8.6 and 9.6 micrometers. In some examples, the detected wavelength of the pyrometer corresponds to infrared wavelengths where the transmissivity of the measured liquid is not more than 60%. If the measured liquid is an aqueous solution (e.g. an acid or just water), the detection wavelength to be selected is in the range of 2.7 to 3.3 μm or 5.9 to 6.3 μm.

In some examples, an output of the pyrometer 50-1 can be used to adjust a temperature of the heating assembly or to detect undesirable dynamic liquid behavior. In other examples, another pyrometer 50-2 may be used in addition to the pyrometer 50-1. An output of the pyrometer 50-1 can be used to adjust a temperature of the heating assembly 40 and an output the pyrometer 50-2 can be used to detect undesirable liquid flow behavior based on an output of the pyrometer 50-2. In some examples, an infrared wavelength detected by the pyrometer 50-1 is greater than 6.5 micrometers and an infrared wavelength detected by the pyrometer 50-2 is between 3 and 4 micrometers. In some examples, an infrared wavelength detected by the pyrometer 50-1 is greater than 6.5 micrometers and an infrared wavelength detected by the pyrometer 50-2 is between 3.3 and 3.5 micrometers.

Referring now to FIG. 4, a controller 90 may be used to control the process. During operation, the controller 90 receives measurement signals from the pyrometers 50-1 and/or 50-2 (collectively pyrometers 50) and selectively controls a temperature of the substrate using the heating assembly. The controller 90 also detects undesirable dynamic liquid behavior such as spiraling and/or splashing based on the measurement signals from the pyrometers 50-1 and/or 50-2. The controller 90 starts, stops and controls a speed of a chuck motor 92 (such as the magnetic motor described above or another type of motor). The controller 90 controls a radial or angular position of the liquid dispensing arm 45 using the arm actuator 52. The controller 90 controls positions of valves 94 to supply the liquid.

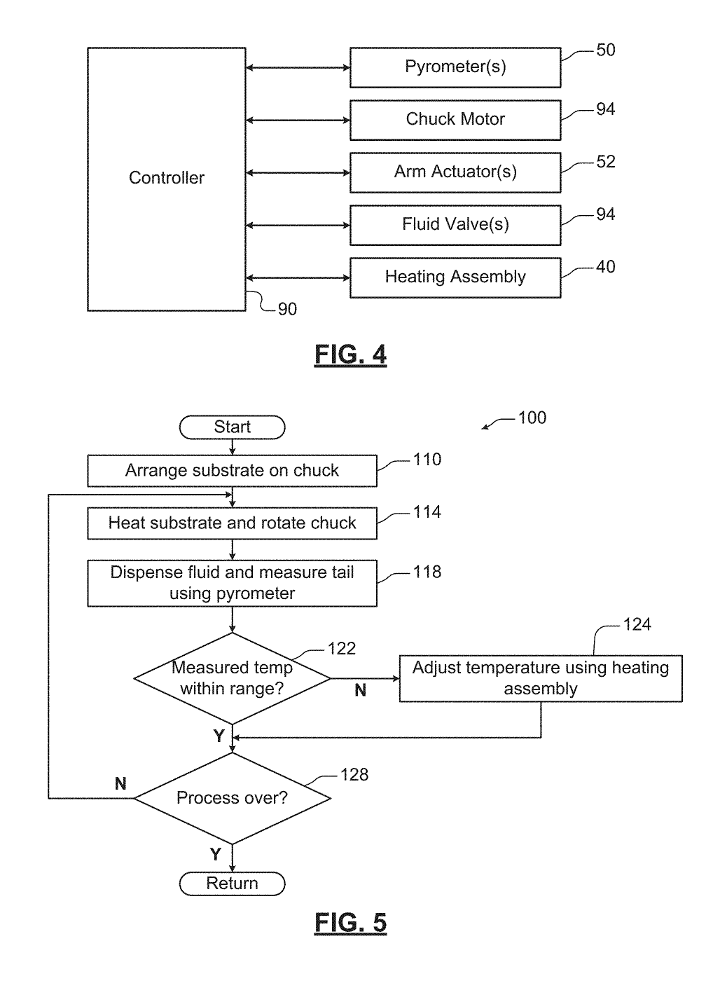

Referring now to FIG. 5, a method 100 for controlling a temperature of the substrate is shown. At 110, a substrate is arranged on the spin chuck. At 114, the substrate is heated by the heating assembly and rotated by the spin chuck. At 118, liquid is dispensed onto the substrate and a tail of the liquid is measured at the detection location using the pyrometers 50-1 and/or 50-2. At 122, the method determines whether the measured temperature is within a predetermined temperature range. If 122 is false, the temperature is adjusted using the heating assembly at 124. The method continues from 122 (if true) and 124 with 128. At 128, the method determines whether the process is over. If 128 is false, the method continues at 114. Otherwise the method returns.

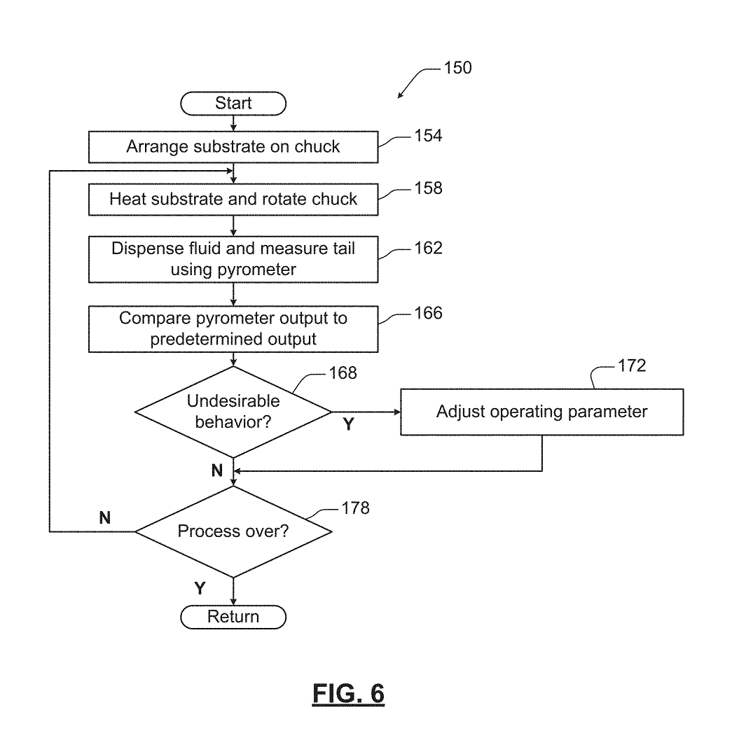

Referring now to FIG. 6, a method 150 for detecting undesirable dynamic liquid behavior is shown. At 154, a substrate is arranged on the spin chuck. At 158, the substrate is heated by the heating assembly and rotated by the spin chuck. At 162, liquid is dispensed onto the substrate and a tail of the liquid is measured using the one or more pyrometers. At 166, the pyrometer output is compared to a predetermined output. At 168, the method determines whether undesirable dynamic liquid behavior is occurring based on the comparison. If 168 is true, one or more operating parameters are adjusted at 172. For example only, the operating parameters may include a temperature of the substrate, a speed of the chuck motor, a flow rate of the liquid, etc. The method continues from 168 (if false) and 172 with 178. At 178, the method determines whether the process is over. If 178 is false, the method continues at 114. Otherwise the method returns. As can be appreciated, the method for controlling temperature and the method for detecting undesirable dynamic liquid behavior can be combined and used concurrently.

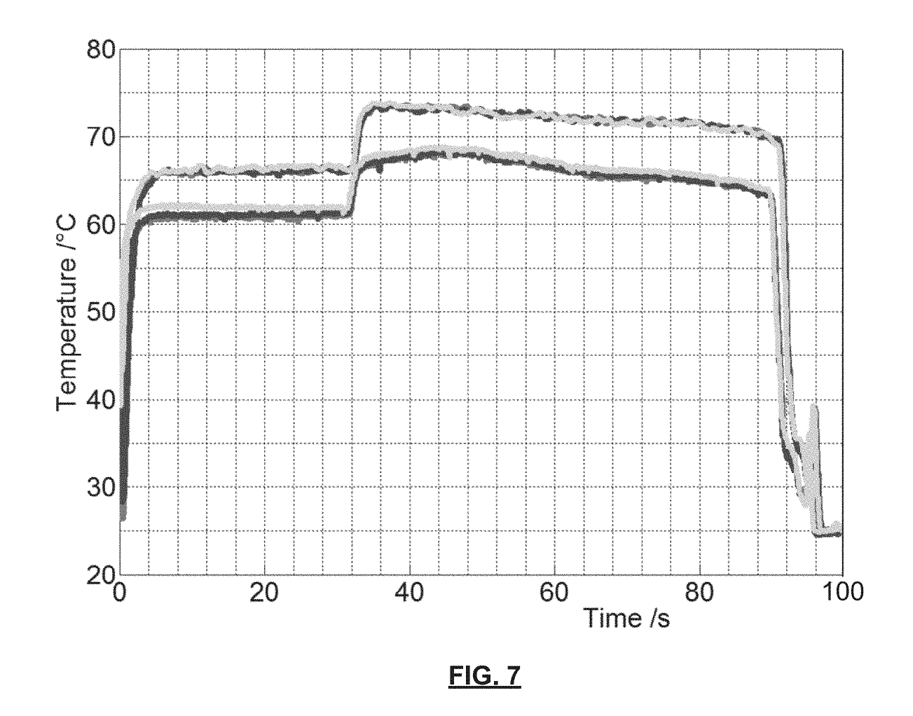

Referring now to FIGS. 7-9, example graphs illustrating measured temperature as a function of time is shown. In FIG. 7, measured temperature is shown as a function of time for a substrate that is normal and is not exhibiting undesirable dynamic liquid behavior. Due to dynamic effects occurring when the liquid is spiraling and/or splashing, the liquid properties change (e.g. film thickness, evaporation, etc. . . . ). As a result, the reading of the pyrometer changes, which provides an indication of undesirable dynamic liquid behavior such as spiraling and/or splashing.

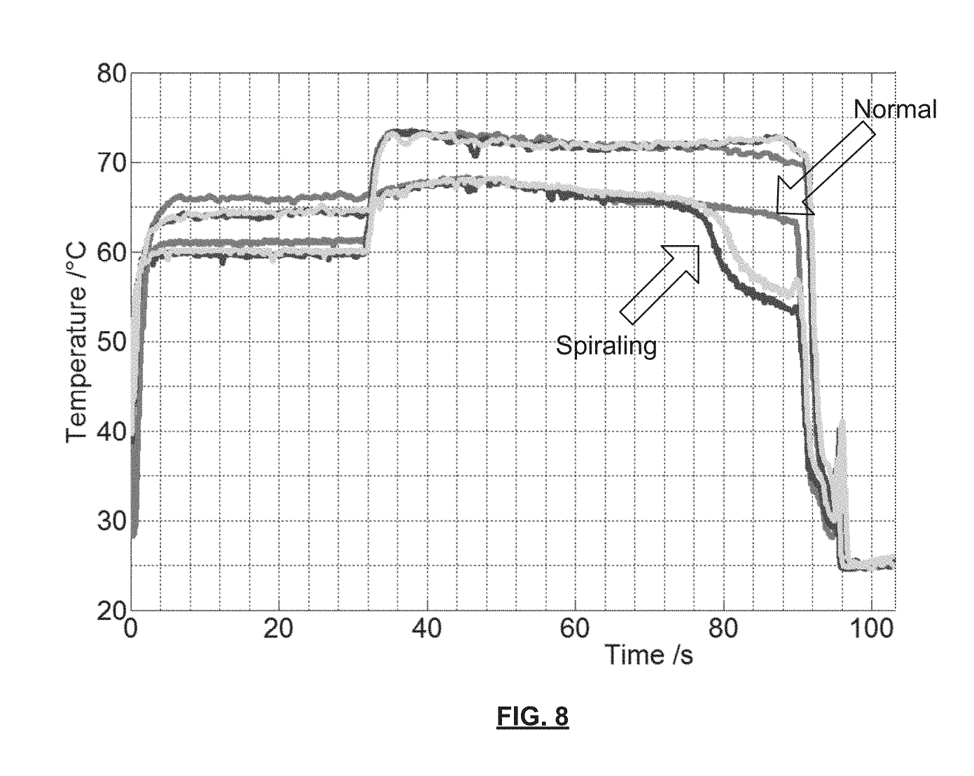

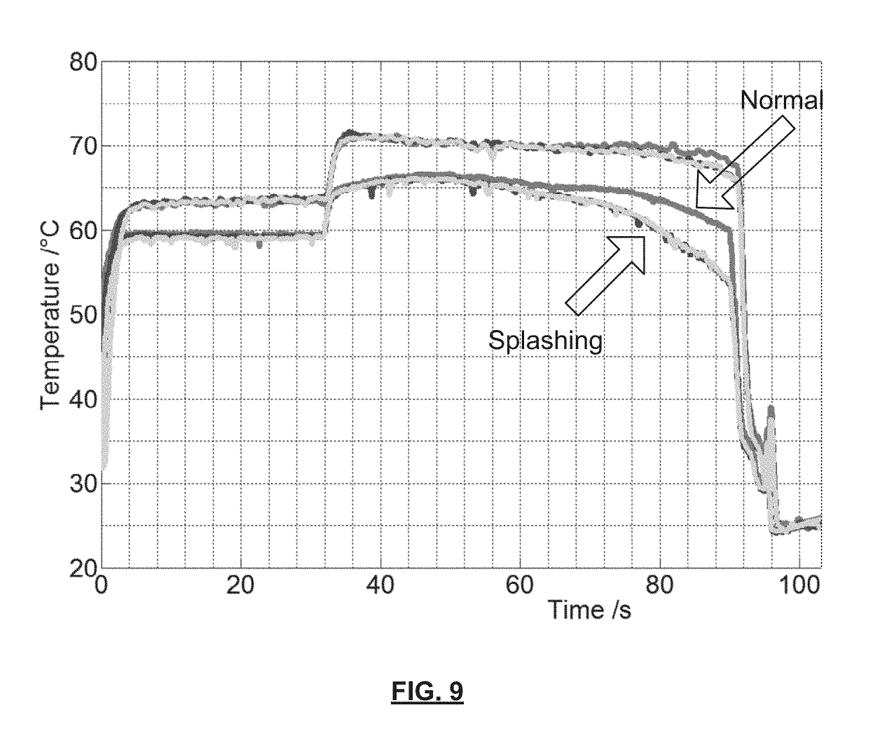

In FIG. 8, measured temperature is shown as a function of time for a substrate that exhibits spiraling (as can be seen by comparison with normal dynamic liquid behavior). In FIG. 9, measured temperature is shown as a function of time for a substrate that exhibits splashing (as can be seen by comparison with normal dynamic liquid behavior).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, liquid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A spin chuck for processing a substrate, comprising:
a chuck configured to engage and rotate a substrate;
a heating assembly that is configured to heat at least one surface of the substrate; and
a liquid dispensing arm that is moveable relative to the substrate and that includes:
a liquid dispensing nozzle attached to the liquid dispensing arm to dispense liquid onto the substrate as the substrate is rotated; and
a first pyrometer attached to the liquid dispensing arm and directed at the liquid dispensed by the liquid dispensing nozzle onto the substrate.

2. The spin chuck of claim 1, wherein:
the liquid dispensed by the liquid dispensing nozzle impacts the substrate at a liquid impact location and forms a tail adjacent to and downstream from the liquid impact location; and
a sensing location of the first pyrometer is directed at the tail of the liquid dispensed onto the substrate spaced from the liquid impact location.

3. The spin chuck of claim 2, wherein a distance from a center of the liquid impact location to a center of the sensing location is in a range from 5 to 100 mm.

4. The spin chuck of claim 2, wherein a distance from a center of the liquid impact location to a center of the sensing location is in a range from 10 to 50 mm.

5. The spin chuck of claim 2, wherein a center of the sensing location is spaced from a rotational center of the substrate by a first distance that is in a range from 1 to 20 mm more than a second distance from a center of the liquid impact location to the rotational center of the substrate.

6. The spin chuck of claim 1, wherein a transmissivity spectrum of the liquid has a local minimum at an infrared wavelength and wherein a measurement wavelength of the first pyrometer corresponds to the infrared wavelength of the local minimum.

7. The spin chuck of claim 6, wherein the infrared wavelength is between one of:
3.3 and 3.5 micrometers; and
8.6 and 9.1 micrometers, for measuring at a transmissivity minimum of the liquid when the liquid includes a secondary alcohol.

8. The spin chuck of claim 6, wherein the infrared wavelength is between one of:
3.3 and 3.5 micrometers; and
9.1 and 9.6 micrometers, for measuring at a transmissivity minimum of the liquid when the liquid includes a primary alcohol.

9. The spin chuck of claim 6, wherein the infrared wavelength is between 8.6 and 9.6 micrometers.

10. The spin chuck of claim 1, further comprising a controller, in communication with the first pyrometer, configured to detect undesirable liquid flow behavior based on an output of the first pyrometer.

11. The spin chuck of claim 10, wherein the controller detects the undesirable liquid flow behavior by comparing an output of the first pyrometer to a predetermined pyrometer output.

12. The spin chuck of claim 1, further comprising a controller, in communication with the first pyrometer, configured to control the heating assembly to adjust a temperature of the substrate in a closed loop manner based on an output of the first pyrometer.

13. The spin chuck of claim 1, further comprising:
a second pyrometer connected to the liquid dispensing arm and directed at the liquid dispensed onto the substrate; and
a controller, in communication with the first pyrometer, configured to at least one of:
adjust a temperature of the heating assembly based on an output of the first pyrometer; and
detect undesirable liquid flow behavior based on an output of the second pyrometer.

14. The spin chuck of claim 13, wherein an infrared wavelength detected by the first pyrometer is greater than 6.5 micrometers and wherein an infrared wavelength detected by the second pyrometer is between 3 and 4 micrometers.

15. The spin chuck of claim 1, wherein the heating assembly includes an array of light emitting diodes (LEDs).

16. The spin chuck of claim 1, wherein the liquid dispensing arm moves the liquid dispensing nozzle and the first pyrometer from a center to an edge of the substrate.

17. The spin chuck of claim 1, wherein the liquid dispensing arm maintains a predetermined distance between the first pyrometer and the substrate as the liquid dispensing arm moves the liquid dispensing nozzle and the first pyrometer.

18. The spin chuck of claim 1, wherein an infrared wavelength of the pyrometer is between one of:
2.7 and 3.3 micrometers; and
5.9 and 6.3 micrometers, for measuring at a transmissivity minimum of the liquid when the liquid is an aqueous solution.

19. The spin chuck of claim 1, wherein a transmissivity spectrum of the liquid is less than 60% at an infrared wavelength and wherein a measurement wavelength of the first pyrometer corresponds to the infrared wavelength.
